(19) United States
(12) Patent Application Publication
(10) Pub. No.: US 2026/0009155 A1
(43) Pub. Date: Jan. 8, 2026

(54) MULTI-LAYERED EPITAXIAL STACK FORMED IN A PRESENCE OF A HIGHER ORDER SILICON PRECURSOR

(71) Applicant: Applied Materials, Inc., Santa Clara, CA (US)

(72) Inventors: Roya BAGHI, Santa Clara, CA (US); Mahendra PAKALA, Santa Clara, CA (US); Arvind KUMAR, Santa Clara, CA (US); Thomas KIRSCHENHEITER, Tempe, AZ (US); Abhishek DUBE, Fremont, CA (US)

(21) Appl. No.: 18/766,209

(22) Filed: Jul. 8, 2024

(51) Int. Cl. C30B 25/22; C30B 25/10; C30B 25/16; C30B 29/52; C30B 31/06

(52) U.S. Cl. CPC C30B 25/22; C30B 25/105; C30B 25/16; C30B 29/52; C30B 31/06

(57) ABSTRACT

A film stack is formed a workpiece. The film stack is fabricated by sequentially depositing a carbon-doped silicon germanium stack and a silicon film to form a carbon-doped silicon-germanium and silicon mini-stack disposed on a substrate during a deposition cycle. The deposition cycle comprises exposing a workpiece including the substrate to a first gas including a first precursor to deposit a first silicon-germanium layer and exposing the workpiece to a second gas including the first precursor to deposit a carbon-silicon-germanium layer on the first silicon-germanium layer. Further, the deposition cycle includes exposing the workpiece to a third gas including the first precursor to deposit a second silicon-germanium layer on the carbon-silicon-germanium layer. The deposition cycle further includes exposing the workpiece to a fourth gas including a second precursor to deposit the silicon film on the second silicon-germanium layer. The second precursor differs from the first precursor.

### BACKGROUND

### Field

Embodiments of the present disclosure generally relate to depositing film stacks using silane and high order silicon precursors.

### Description of the Related Art

Microelectronic technology has advanced at a rapid pace and device dimensions have shrunk with advancing technology to provide faster processing and storage per unit space. As microelectronic technology advances, the market demands smaller chips with increasingly more structures per unit area. One class of devices which has seen many advances in miniaturization are memory devices.

Two of the mainstays of the memory segment are NOT-AND (NAND) flash memory devices and dynamic random-access memory (DRAM) devices. An example DRAM device is a three-dimensional DRAM (3D-DRAM) device. DRAM devices are dynamic, volatile and very fast. Accordingly, DRAM devices are well suited for short term system memory. DRAM devices have continued the path of scaling to smaller cell designs. This dimension shrink has driven the introduction of multiple patterning technology. Many of the DRAM devices contain epitaxial film stacks. Any crystal imperfections and/or defects cause leakage in the DRAM device. The imperfections and defects are roadblocks for forming taller film stacks to increase the size of the memory devices.

In various examples, carbon has been incorporated into the film stack to reduce defects. However, using carbon reduces the growth rate for the layers within the film stack as lower temperatures are used when carbon is incorporated.

Therefore, a need exists for an improved process for forming layers incorporating carbon within a film stack to form a memory device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A depicts a workpiece containing a multi-layered epitaxial stack disposed on a substrate, according to one or more embodiments described and discussed herein.

FIG. 1B depicts a workpiece containing a multi-layered epitaxial stack disposed on a substrate, according to one or more embodiments described and discussed herein.

FIG. 2A is a flowchart depicting a method for fabricating a multi-layered epitaxial stack, according to one or more embodiments described and discussed herein.

FIG. 2B is a flowchart depicting a method for fabricating a multi-layered epitaxial stack, according to one or more embodiments described and discussed herein.

FIG. 3A is a flowchart depicting a method for fabricating a multi-layered epitaxial stack in the presence of a plasma, according to one or more embodiments described and discussed herein.

FIG. 3B is a flowchart depicting a method for fabricating a multi-layered epitaxial stack in the presence of a plasma, according to one or more embodiments described and discussed herein.

FIG. 4 illustrates a schematic top view of a multi-chamber processing system that may be used to perform the methods of FIGS. 2A, 2B, 3A, and 3B according to one or more embodiments.

To facilitate understanding, identical reference numerals have been used, where possible, to designate identical elements that are common to the Figures. It is contemplated that elements and features of one or more embodiments may be beneficially incorporated in other embodiments.

### SUMMARY

In one example, a method of fabricating a film stack includes sequentially depositing a carbon-doped silicon germanium stack and a silicon film to form a carbon-doped silicon-germanium and silicon mini-stack disposed on a substrate during a deposition cycle. The deposition cycle comprises exposing a workpiece including the substrate to a first gas including a first precursor to deposit a first silicon-germanium layer and exposing the workpiece to a second gas including the first precursor to deposit a carbon-silicon-germanium layer on the first silicon-germanium layer. Further, the deposition cycle includes exposing the workpiece to a third gas including the first precursor to deposit a second silicon-germanium layer on the carbon-silicon-germanium layer. The deposition cycle further includes exposing the workpiece to a fourth gas including a second precursor to deposit the silicon film on the second silicon-germanium layer. The second precursor differs from the first precursor.

In one example, a processing chamber sequentially deposits a carbon-doped silicon germanium stack and a silicon film to form a carbon-doped silicon-germanium and silicon mini-stack disposed on a substrate during a deposition cycle. The deposition cycle includes exposing a workpiece comprising the substrate to a first gas including a first precursor to deposit a first silicon-germanium layer, and exposing the workpiece to a second gas including the first precursor to deposit a carbon-silicon-germanium layer on the first silicon-germanium layer. Further, the deposition cycle includes exposing the workpiece to a third gas including the first precursor to deposit a second silicon-germanium layer on the carbon-silicon-germanium layer. The deposition cycle further includes exposing the workpiece to a fourth gas including a second precursor to deposit the silicon film on the second silicon-germanium layer. The second precursor differs from the first precursor.

In one example, a workpiece includes a multi-layered epitaxial stack disposed on a substrate. The multi-layered epitaxial stack includes a plurality of carbon-doped silicon-germanium stacks. Each of the plurality of carbon-doped silicon-germanium stacks is deposited in a presence of a first precursor. The multi-layered epitaxial stack further includes plurality of silicon films. Each of the plurality of silicon films is deposited on a respective one of the plurality of carbon-doped silicon-germanium stacks. Each of the plurality of silicon films is deposited in a presence of a second precursor. The second precursor differs from the first precursor.

### DETAILED DESCRIPTION

Embodiments of the present disclosure generally relate to epitaxial film stacks and deposition processes for preparing the epitaxial film stacks. The epitaxial film stacks can be or include a carbon-doped silicon-germanium and silicon mini-stack produced on a substrate. The carbon-doped silicon-germanium and silicon mini-stack has relatively low defects or crystal imperfections, such as a slipline count of less than 6,000 sliplines, less than 3,000 sliplines, less than 2,000 sliplines, or even lower. The methods for depositing or otherwise preparing epitaxial film stacks can be utilized to produce epitaxial film stacks used throughout the microelectronics industry including as a memory device. In one or more examples, the memory device is a three-dimensional, dynamic random access memory (3D-DRAM) device.

Introducing carbon within the silicon-germanium (e.g., using carbon-doped silicon-germanium) mitigates defects and crystal imperfections within the film stacks. However, using a carbon-doped silicon germanium reduces the growth rate for the layers within the film stack as lower temperatures are used when carbon is introduced.

The epitaxial film stacks and deposition process described in some embodiments described herein uses a silane precursor during the deposition of carbon-doped silicon germanium layers, and a higher order silicon precursor (e.g., disilane, trisilane, tetrasilane, or other higher order silanes) during the deposition of silicon layers. The use of a higher order silicon precursor increases the growth rate of the silicon layers at the lower temperatures used for the deposition of the carbon-doped silicon germanium layers. Accordingly, memory devices formed with the epitaxial film stacks and deposition process described herein can be used to form vertically larger stacks as compared to epitaxial film stacks and a deposition process that does not use a higher order silicon precursor during the deposition of a silicon layer.

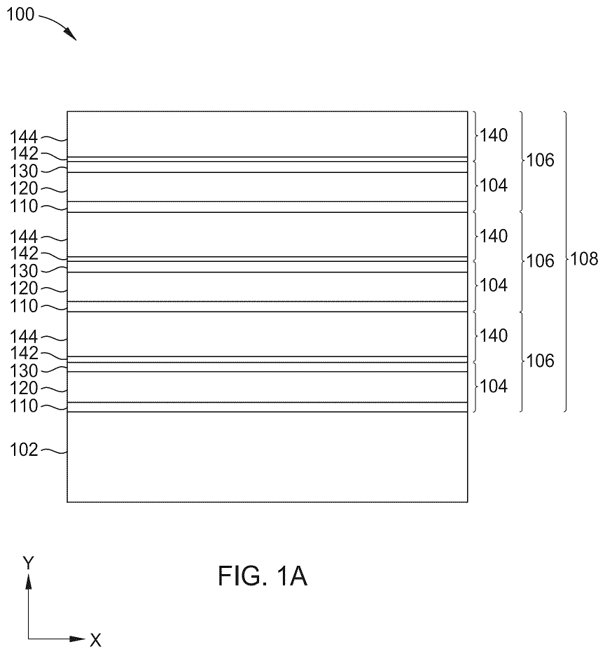

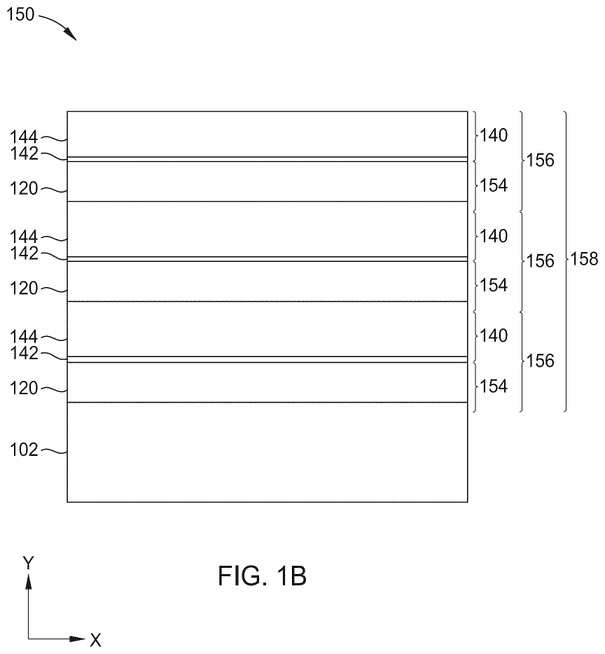

FIG. 1A depicts a workpiece 100 containing a multi-layered epitaxial stack 108 disposed on a substrate 102, according to one or more examples described and discussed herein. In one example, the workpiece 100 is integrated into a memory device. The memory device may be a DRAM device. In one example, the memory device is a 3D-DRAM device.

The substrate 102 is a silicon substrate. In another example, the substrate 102 is another type of substrate.

The multi-layered epitaxial stack 108 contains a plurality (e.g., two, three, or more) of carbon-doped silicon-germanium and silicon mini-stacks 106. Each of the carbon-doped silicon-germanium and silicon mini-stacks 106 contains a carbon-doped silicon germanium stack 104 and a silicon film 140. In one example, the carbon-doped silicon germanium stack 104 is disposed on the silicon film 140. In another example, the order can be reversed such that the silicon film 140 is disposed on the carbon-doped silicon germanium stack 104.

The carbon-doped silicon germanium stack 104 contains a carbon-silicon-germanium layer 120 disposed between a first silicon-germanium layer 110 and a second silicon-germanium layer 130. In some examples, the first silicon-germanium layer 110 and the second silicon-germanium layer 130 have the same composition, but in other examples, the first silicon-germanium layer 110 and the second silicon-germanium layer 130 can have different compositions relative to each other. The carbon-doped silicon germanium stack 104 has a width in the Y direction of about 10 nm. In other examples, the carbon-doped silicon germanium stack has a width in the Y direction of less than or greater than 10 nm.

The silicon film 140 contains a silicon bulk layer 144 disposed on a silicon seed layer 142. In some embodiments, the silicon seed layer 142 can be omitted and the silicon bulk layer 144 can be deposited directly on the second silicon-germanium layer 130. Each of the silicon seed layer 142 and the silicon bulk layer 144 can independently contain one or more silicon materials, such as epitaxial silicon, crystalline silicon, any dopant thereof, or any combination thereof. In one example, the silicon layer 140 has a width of about 70 nm. In other examples, the silicon layer 140 has a width that is greater than or less than about 70 nm.

In one example, to increase the growth rate of the silicon film 140, a precursor containing a higher order silicon gas (e.g., disilane, trisilane, or tetrasilane, among others) is used during the deposition of the silicon film 140 and a precursor gas containing silicon is used during the deposition of the carbon-doped silicon germanium stack 104. Using a higher order silicon gas as a precursor during the deposition of the silicon film 140 increases the growth rate of the silicon film 140 when lower temperatures are used during the deposition process due to the inclusion of carbon.

FIG. 1A depicts the workpiece 100 containing the carbon-doped silicon-germanium and silicon mini-stack 108 disposed on the substrate 102. The carbon-doped silicon-germanium and silicon mini-stack 108 can be a portion of a memory device. In one or more examples, the memory device is a 3D-DRAM device.

The substrate 102 can be or include any suitable substrate material. In one or more embodiments, the substrate 102 contains one or more semiconductor materials and/or dopants, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, dopants thereof, or any combination thereof. Although a few examples of materials from which the substrate 102 may be formed are described herein, any material that may serve as a foundation upon which passive and active electronic devices (e.g., memories, transistors, capacitors, inductors, resistors, switches, integrated circuits, amplifiers, optoelectronic devices, or any other electronic devices) may be fabricated is within the spirit and scope of the present disclosure. In one or more examples, the substrate 102 can be or contain silicon, a silicon germanium compound, a silicon germanium carbon compound, or any dopant thereof.

Each of the first silicon-germanium layer 110 and the second silicon-germanium layer 130 independently contains a silicon-germanium material which includes at least silicon and germanium. The silicon-germanium material can be doped or undoped. In one or more embodiments, each of the first silicon-germanium layer 110, the second silicon-germanium layer 130, and/or the silicon-germanium material independently contains a concentration of germanium in a range from about 5 atomic percent (at %), about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the first silicon-germanium layer 110, the second silicon-germanium layer 130, and/or the silicon-germanium material independently contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

In some embodiments, each of the first silicon-germanium layer 110, the second silicon-germanium layer 130, and/or the silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the first silicon-germanium layer 110, the second silicon-germanium layer 130, and/or the silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

In one or more examples, each of the first silicon-germanium layer 110, the second silicon-germanium layer 130, and/or the silicon-germanium material independently contains about 10 at % to about 30 at % of germanium and about 70 at % to about 90 at % of silicon. In other examples, each of the first silicon-germanium layer 110, the second silicon-germanium layer 130, and/or the silicon-germanium material independently contains about 15 at % to about 25 at % of germanium and about 75 at % to about 85 at % of silicon.

In one or more embodiments, each of the first silicon-germanium layer 110 and the second silicon-germanium layer 130 independently has a thickness in a range from about 0.5 nm to about 10 nm. In other examples, the first silicon-germanium layer 110 has a thickness of less than 0.5 nm.

The carbon-silicon-germanium layer 120 contains carbon-silicon-germanium material which includes at least silicon, germanium, and carbon. The carbon-silicon-germanium material can be doped or undoped. In one or more embodiments, each of the carbon-silicon-germanium layer 120 and/or the carbon-silicon-germanium material independently contains a concentration of germanium in a range from about 5 at %, about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the carbon-silicon-germanium layer 120 and/or the carbon-silicon-germanium material independently contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

Each of the carbon-silicon-germanium layer 120 and/or the carbon-silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the carbon-silicon-germanium layer 120 and/or the carbon-silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

Each of the carbon-silicon-germanium layer 120 and/or the carbon-silicon-germanium material independently contains a concentration of carbon in a range from about 0.1 at %, about 0.2 at %, about 0.3 at %, about 0.4 at %, about 0.5 at %, about 0.6 at %, about 0.8 at %, or about 1 at % to about 1.2 at %, about 1.5 at %, about 1.8 at %, about 2 at %, about 2.2 at %, about 2.5 at %, about 2.8 at %, about 3 at %, about 3.5 at %, about 4 at %, about 4.5 at %, or about 5 at %. For example, each of the carbon-silicon-germanium layer 120 and/or the carbon-silicon-germanium material independently contains about 0.1 at % to about 5 at %, about 0.2 at % to about 5 at %, about 0.2 at % to about 4 at %, about 0.2 at % to about 3.5 at %, about 0.2 at % to about 3 at %, about 0.2 at % to about 2.5 at %, about 0.2 at % to about 2 at %, about 0.2 at % to about 1.8 at %, about 0.2 at % to about 1.5 at %, about 0.2 at % to about 1.2 at %, about 0.2 at % to about 1 at %, about 0.2 at % to about 0.8 at %, about 0.2 at % to about 0.5 at %, about 0.5 at % to about 5 at %, about 0.5 at % to about 4 at %, about 0.5 at % to about 3.5 at %, about 0.5 at % to about 3 at %, about 0.5 at % to about 2.5 at %, about 0.5 at % to about 2 at %, about 0.5 at % to about 1.8 at %, about 0.5 at % to about 1.5 at %, about 0.5 at % to about 1.2 at %, about 0.5 at % to about 1 at %, about 0.5 at % to about 0.8 at %, about 1 at % to about 5 at %, about 1 at % to about 4 at %, about 1 at % to about 3.5 at %, about 1 at % to about 3 at %, about 1 at % to about 2.5 at %, about 1 at % to about 2 at %, about 1 at % to about 1.8 at %, about 1 at % to about 1.5 at %, about 1 at % to about 1.2 at % of carbon.

In one or more examples, each of the carbon-silicon-germanium layer 120 and/or the carbon-silicon-germanium material independently contains about 70 at % to about 90 at % of silicon, about 10 at % to about 30 at % of germanium, and about 0.2 at % to about 3 at % of carbon. In some examples, each of the carbon-silicon-germanium layer 120 and/or the carbon-silicon-germanium material independently contains about 75 at % to about 85 at % of silicon, about 15 at % to about 25 at % of germanium, and about 0.5 at % to about 1.5 at % of carbon. In other examples, each of the carbon-silicon-germanium layer 120 and/or the carbon-silicon-germanium material independently contains about 78 at % to about 82 at % of silicon, about 18 at % to about 22 at % of germanium, and about 0.8 at % to about 1.2 at % of carbon.

In one or more embodiments, the carbon-silicon-germanium layer 120 has a thickness in a range from about 0.5 nm, about 1 nm, about 2 nm, about 3 nm, about 4 nm, about 5 nm, about 6 nm, about 8 nm, or about 10 nm to about 12 nm, about 14 nm, about 15 nm, about 16 nm, about 18 nm, about 20 nm, about 25 nm, or thicker. In one example, the thickness of the carbon-silicon-germanium layer 120 is about 10 nm. In other examples, the thickness of the carbon-silicon-germanium layer 120 is less than or greater than about 10 nm.

The carbon-doped silicon germanium stack 104 has a thickness in a range from about 1 nm, about 2 nm, about 3 nm, about 5 nm, about 6 nm, about 8 nm, or about 10 nm to about 12 nm, about 15 nm, about 18 nm, about 20 nm, about 25 nm, about 30 nm, about 40 nm, about 50 nm, or thicker. For example, the carbon-doped silicon germanium stack 104 has a thickness of about 1 nm to about 50 nm, about 5 nm to about 50 nm, about 5 nm to about 40 nm, about 5 nm to about 35 nm, about 5 nm to about 30 nm, about 5 nm to about 25 nm, about 5 nm to about 20 nm, about 5 nm to about 18 nm, about 5 nm to about 15 nm, about 5 nm to about 10 nm, about 5 nm to about 8 nm, about 10 nm to about 50 nm, about 10 nm to about 40 nm, about 10 nm to about 35 nm, about 10 nm to about 30 nm, about 10 nm to about 25 nm, about 10 nm to about 20 nm, about 10 nm to about 18 nm, about 10 nm to about 15 nm, about 10 nm to about 12 nm, about 15 nm to about 50 nm, about 15 nm to about 40 nm, about 15 nm to about 35 nm, about 15 nm to about 30 nm, about 15 nm to about 25 nm, about 15 nm to about 20 nm, or about 15 nm to about 18 nm. In one example, the thickness of the carbon-doped silicon germanium stack 104 is about 10 nm. In other examples, the thickness of the carbon-doped silicon germanium stack 104 is less than or greater than about 10 nm.

The silicon seed layer 142 has a thickness in a range from about 0.05 nm, about 0.1 nm, about 0.2 nm, about 0.3 nm, about 0.4 nm, about 0.5 nm, about 0.6 nm, or to about 0.7 nm, about 0.8 nm, about 0.9 nm, about 1 nm, about 1.2 nm, about 1.5 nm, about 1.8 nm, about 2 nm, about 2.5 nm, about 3 nm, about 4 nm, about 5 nm, or thicker. For example, the silicon seed layer 142 has a thickness of about 0.05 nm to about 5 nm, about 0.05 nm to about 3 nm, about 0.05 nm to about 2 nm, about 0.05 nm to about 1 nm, about 0.05 nm to about 0.5 nm, about 0.1 nm to about 5 nm, about 0.1 nm to about 3 nm, about 0.1 nm to about 2 nm, about 0.1 nm to about 1 nm, about 0.1 nm to about 0.5 nm, about 0.5 nm to about 5 nm, about 0.5 nm to about 3 nm, about 0.5 nm to about 2 nm, about 0.5 nm to about 1 nm. In one example, the silicon seed layer 142 is omitted.

The silicon bulk layer 144 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the silicon bulk layer 144 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

The silicon film 140 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the silicon film 140 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

FIG. 1A depicts the multi-layered epitaxial stack 108 containing three the carbon-doped silicon-germanium and silicon mini-stacks 106 disposed on the substrate 102. However, the multi-layered epitaxial stack 108 may have a variety of different amounts of the carbon-doped silicon-germanium and silicon mini-stack 106 disposed on the substrate 102. The multi-layered epitaxial stack 108 may contain a range from 1 stack, 2 stacks, 3 stacks, 4 stacks, 5 stacks, 6 stacks, 7 stacks, 8 stacks, about 10 stacks, about 12 stacks, about 15 stacks, about 18 stacks, about 20 stacks, about 25 stacks, about 30 stacks, about 35 stacks, about 40 stacks, about 45 stacks, or about 50 stacks to about 55 stacks, about 60 stacks, about 70 stacks, about 80 stacks, about 90 stacks, about 100 stacks, about 110 stacks, about 120 stacks, about 130 stacks, about 140 stacks, about 150 stacks, about 160 stacks, about 170 stacks, about 180 stacks, about 190 stacks, about 200 stacks, about 220 stacks, about 250 stacks, about 300 stacks, or more of the carbon-doped silicon-germanium and silicon mini-stack 106. For example, the multi-layered epitaxial stack 108 may contain about 2 stacks to about 300 stacks, about 5 stacks to about 250 stacks, about 10 stacks to about 200 stacks, about 20 stacks to about 200 stacks, about 30 stacks to about 200 stacks, about 35 stacks to about 200 stacks, about 40 stacks to about 200 stacks, about 50 stacks to about 200 stacks, about 60 stacks to about 200 stacks, about 80 stacks to about 200 stacks, about 100 stacks to about 200 stacks, about 120 stacks to about 200 stacks, about 150 stacks to about 200 stacks, about 180 stacks to about 200 stacks, about 10 stacks to about 100 stacks, about 20 stacks to about 100 stacks, about 30 stacks to about 100 stacks, about 35 stacks to about 100 stacks, about 40 stacks to about 100 stacks, about 50 stacks to about 100 stacks, about 60 stacks to about 100 stacks, about 80 stacks to about 100 stacks, about 90 stacks to about 100 stacks, about 10 stacks to about 90 stacks, about 10 stacks to about 80 stacks, about 10 stacks to about 70 stacks, about 10 stacks to about 60 stacks, about 10 stacks to about 50 stacks, about 10 stacks to about 40 stacks, about 10 stacks to about 35 stacks, about 10 stacks to about 30 stacks, about 10 stacks to about 25 stacks, about 10 stacks to about 20 stacks, or about 10 stacks to about 15 stacks of the carbon-doped silicon-germanium and silicon mini-stack 106. In one or more examples, the multi-layered epitaxial stack 108 contains about 10 stacks to about 200 stacks of the plurality of carbon-doped silicon-germanium and silicon mini-stacks 106. In some examples, the multi-layered epitaxial stack 108 contains about 30 stacks to about 100 stacks of the plurality of carbon-doped silicon-germanium and silicon mini-stacks 106. In other examples, the multi-layered epitaxial stack 108 contains about 35 stacks to about 75 stacks of the plurality of carbon-doped silicon-germanium and silicon mini-stacks 106.

FIG. 1B depicts a workpiece 150 containing a multi-layered epitaxial stack 158 disposed on a substrate 102, according to one or more examples described and discussed herein. In one example, the workpiece 150 is integrated into a memory device. The memory device may be a DRAM device. In one example, the memory device is a 3D-DRAM device.

The multi-layered epitaxial stack 158 contains a plurality (e.g., two, three, or more) of carbon-doped silicon-germanium and silicon mini-stacks 156. Each of the carbon-doped silicon-germanium and silicon mini-stacks 156 contains a carbon-doped silicon germanium stack 154 and a silicon film 140. In one example, the carbon-doped silicon germanium stack 154 is disposed on the silicon film 140. In another example, the order can be reversed such that the silicon film 140 is disposed on the carbon-doped silicon germanium stack 154.

The carbon-doped silicon germanium stack 154 contains a carbon-silicon-germanium layer 120. As compared to the carbon-doped silicon germanium stack 104, the carbon-doped silicon germanium stack 154 does not include a first silicon-germanium layer 110 and a second silicon-germanium layer 130. The carbon-doped silicon germanium stack 154 has a width in the Y direction of about 10 nm. In other examples, the carbon-doped silicon germanium stack has a width in the Y direction of less than or greater than 10 nm.

The silicon film 140 contains a silicon bulk layer 144 disposed on a silicon seed layer 142. In some embodiments, the silicon seed layer 142 can be omitted and the silicon bulk layer 144 can be deposited directly on the second silicon-germanium layer 130. Each of the silicon seed layer 142 and the silicon bulk layer 144 can independently contain one or more silicon materials, such as epitaxial silicon, crystalline silicon, any dopant thereof, or any combination thereof. In one example, the silicon layer 140 has a width of about 70 nm. In other examples, the silicon layer 140 has a width that is greater than or less than about 70 nm.

In one example, to increase the growth rate of the silicon film 140, a precursor containing a higher order silicon gas (e.g., disilane, trisilane, or tetrasilane, among others) is used during the deposition of the silicon film 140 and a precursor gas containing silicon is used during the deposition of the carbon-doped silicon germanium stack 154. Using a higher order silicon gas as a precursor during the deposition of the silicon film 140 increases the growth rate of the silicon film 140 when lower temperatures are used during the deposition process due to the inclusion of carbon.

FIG. 1B depicts the workpiece 150 containing the carbon-doped silicon-germanium and silicon mini-stack 158 disposed on the substrate 102. The carbon-doped silicon-germanium and silicon mini-stack 158 can be a portion of a memory device. In one or more examples, the memory device is a 3D-DRAM device.

The substrate 102 can be or include any suitable substrate material. In one or more embodiments, the substrate 102 contains one or more semiconductor materials and/or dopants, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, dopants thereof, or any combination thereof. Although a few examples of materials from which the substrate 102 may be formed are described herein, any material that may serve as a foundation upon which passive and active electronic devices (e.g., memories, transistors, capacitors, inductors, resistors, switches, integrated circuits, amplifiers, optoelectronic devices, or any other electronic devices) may be fabricated is within the spirit and scope of the present disclosure. In one or more examples, the substrate 102 can be or contain silicon, a silicon germanium compound, a silicon germanium carbon compound, or any dopant thereof.

The carbon-silicon-germanium layer 120 is described in greater detail above with regard to FIG. 1A.

The carbon-doped silicon germanium stack 154 has a thickness in a range from about 1 nm, about 2 nm, about 3 nm, about 5 nm, about 6 nm, about 8 nm, or about 10 nm to about 12 nm, about 15 nm, about 18 nm, about 20 nm, about 25 nm, about 30 nm, about 40 nm, about 50 nm, or thicker. For example, the carbon-doped silicon germanium stack 154 has a thickness of about 1 nm to about 50 nm, about 5 nm to about 50 nm, about 5 nm to about 40 nm, about 5 nm to about 35 nm, about 5 nm to about 30 nm, about 5 nm to about 25 nm, about 5 nm to about 20 nm, about 5 nm to about 18 nm, about 5 nm to about 15 nm, about 5 nm to about 10 nm, about 5 nm to about 8 nm, about 10 nm to about 50 nm, about 10 nm to about 40 nm, about 10 nm to about 35 nm, about 10 nm to about 30 nm, about 10 nm to about 25 nm, about 10 nm to about 20 nm, about 10 nm to about 18 nm, about 10 nm to about 15 nm, about 10 nm to about 12 nm, about 15 nm to about 50 nm, about 15 nm to about 40 nm, about 15 nm to about 35 nm, about 15 nm to about 30 nm, about 15 nm to about 25 nm, about 15 nm to about 20 nm, or about 15 nm to about 18 nm. In one example, the thickness of the carbon-doped silicon germanium stack 154 is about 10 nm. In other examples, the thickness of the carbon-doped silicon germanium stack 154 is less than or greater than about 10 nm.

The silicon seed layer 142 is described in greater detail with regard to FIG. 1A. The silicon bulk layer 144 is described in greater detail with regard to FIG. 1A. The silicon film 140 is described in greater detail with regard to FIG. 1A.

FIG. 1B depicts the multi-layered epitaxial stack 158 containing three the carbon-doped silicon-germanium and silicon mini-stacks 156 disposed on the substrate 102. However, the multi-layered epitaxial stack 158 may have a variety of different amounts of the carbon-doped silicon-germanium and silicon mini-stack 156 disposed on the substrate 102. The multi-layered epitaxial stack 158 may contain a range from 1 stack, 2 stacks, 3 stacks, 4 stacks, 5 stacks, 6 stacks, 7 stacks, 8 stacks, about 10 stacks, about 12 stacks, about 15 stacks, about 18 stacks, about 20 stacks, about 25 stacks, about 30 stacks, about 35 stacks, about 40 stacks, about 45 stacks, or about 50 stacks to about 55 stacks, about 60 stacks, about 70 stacks, about 80 stacks, about 90 stacks, about 100 stacks, about 110 stacks, about 120 stacks, about 130 stacks, about 140 stacks, about 150 stacks, about 160 stacks, about 170 stacks, about 180 stacks, about 190 stacks, about 200 stacks, about 220 stacks, about 250 stacks, about 300 stacks, or more of the carbon-doped silicon-germanium and silicon mini-stack 156. For example, the multi-layered epitaxial stack 158 may contain about 2 stacks to about 300 stacks, about 5 stacks to about 250 stacks, about 10 stacks to about 200 stacks, about 20 stacks to about 200 stacks, about 30 stacks to about 200 stacks, about 35 stacks to about 200 stacks, about 40 stacks to about 200 stacks, about 50 stacks to about 200 stacks, about 60 stacks to about 200 stacks, about 80 stacks to about 200 stacks, about 100 stacks to about 200 stacks, about 120 stacks to about 200 stacks, about 150 stacks to about 200 stacks, about 180 stacks to about 200 stacks, about 10 stacks to about 100 stacks, about 20 stacks to about 100 stacks, about 30 stacks to about 100 stacks, about 35 stacks to about 100 stacks, about 40 stacks to about 100 stacks, about 50 stacks to about 100 stacks, about 60 stacks to about 100 stacks, about 80 stacks to about 100 stacks, about 90 stacks to about 100 stacks, about 10 stacks to about 90 stacks, about 10 stacks to about 80 stacks, about 10 stacks to about 70 stacks, about 10 stacks to about 60 stacks, about 10 stacks to about 50 stacks, about 10 stacks to about 40 stacks, about 10 stacks to about 35 stacks, about 10 stacks to about 30 stacks, about 10 stacks to about 25 stacks, about 10 stacks to about 20 stacks, or about 10 stacks to about 15 stacks of the carbon-doped silicon-germanium and silicon mini-stack 156. In one or more examples, the multi-layered epitaxial stack 158 contains about 10 stacks to about 200 stacks of the plurality of carbon-doped silicon-germanium and silicon mini-stacks 156. In some examples, the multi-layered epitaxial stack 158 contains about 30 stacks to about 100 stacks of the plurality of carbon-doped silicon-germanium and silicon mini-stacks 156. In other examples, the multi-layered epitaxial stack 158 contains about 35 stacks to about 75 stacks of the plurality of carbon-doped silicon-germanium and silicon mini-stacks 156.

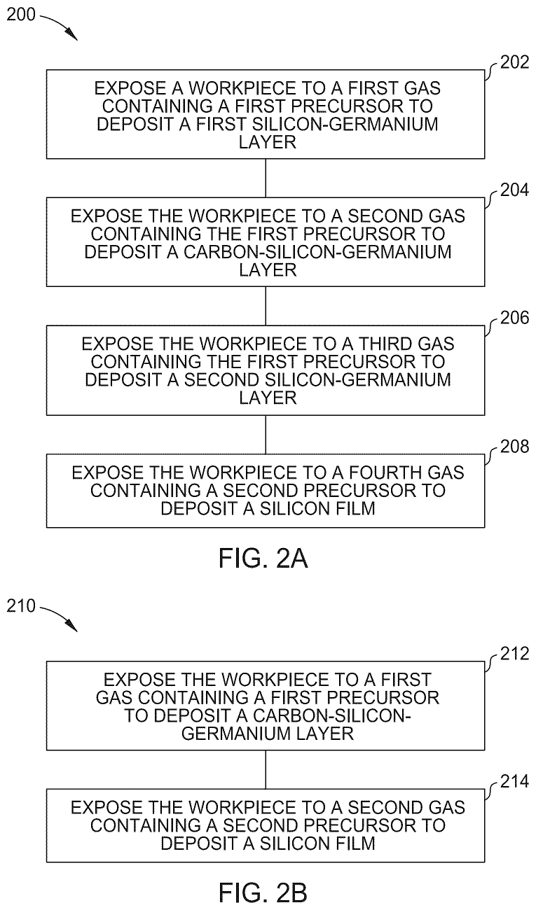

FIG. 2A is a flowchart depicting a process or method 200 for fabricating a multi-layered epitaxial stack, such as the multi-layered epitaxial stack 108 disposed on the substrate 102, according to one or more embodiments described and discussed herein. Other multi-layered epitaxial stacks and various film stacks can be deposited, fabricated, or otherwise produced by the method 200.

In one or more embodiments, the method 200 is provided and includes sequentially depositing a carbon-doped silicon germanium stack 104 and a silicon film 140 to form a carbon-doped silicon-germanium and silicon mini-stack disposed on a substrate 102 during a deposition cycle. The method 200 includes repeating the deposition cycle to prepare a multi-layered epitaxial stack 108 containing one or more of the carbon-doped silicon-germanium and silicon mini-stacks 106 on the substrate 102.

At operation 202 of the method 200, the deposition cycle includes exposing the workpiece containing a substrate to a first gas containing a first precursor to deposit a first silicon-germanium layer. With reference to FIG. 1A, the workpiece 100 containing the substrate 102 is exposed to one or more of a silicon precursor, a silicon-chlorine precursor, a germanium precursor, and a carrier gas to deposit a first silicon-germanium layer 110. The silicon precursor contains silane. The silicon-chlorine precursor can be or contain one or more of monochlorosilane, dichlorosilane, trichlorosilane, tetracholorosilane, hexachlorodisilane, or any combination thereof. The germanium precursor can be or contain one or more of germane, tetrachlorogermane, one or more organogermane compounds, or any combination thereof. The carrier gas can be or contain on or more of hydrogen (H₂), nitrogen (N₂), argon, helium, or any combination thereof. In some examples, the carrier gas contains a mixture of hydrogen and nitrogen. The mixture of hydrogen and nitrogen can have a hydrogen to nitrogen molar ratio in a range from about 1:10 to about 10:1, about 1:5 to about 5:1, about 1:3 to about 3:1, about 1:2 to about 2:1, or about 1:1.

At operation 204 of the method 200, the deposition cycle includes exposing the workpiece to a second gas to deposit a carbon-silicon-germanium layer on the first silicon-germanium layer. With reference to FIG. 1A, the workpiece 100 is exposed to a second gas containing the silicon precursor, the silicon-chlorine precursor, the silicon-carbon precursor, the germanium precursor, and the carrier gas to deposit the carbon-silicon-germanium layer 120 on the first silicon-germanium layer 110.

In one example, after the operation 202 and before the operation 204 the flow of one or more silicon-carbon precursors is started. The silicon-carbon precursor contains one or more alkylsilanes. In some examples, the silicon-carbon precursor can be or contain methylsilane, dimethylsilane, or any combination thereof.

In one example after the completion of the operation 204, the deposition cycle includes ceasing the flow of the one or more silicon-carbon precursors.

At operation 206 of the method 200, the deposition cycle includes exposing the workpiece to a third gas containing the first precursor to deposit a second silicon-germanium layer on the carbon-silicon-germanium layer. The third gas contains the silicon precursor, the silicon-chlorine precursor, and the germanium precursor. With reference to FIG. 1A, exposing the workpiece to the third gas and the carrier gas deposits a second silicon-germanium layer 130 on the carbon-silicon-germanium layer 120.

In one example after the completion of the operation 206, the deposition cycle includes ceasing the flow of the germanium precursor.

At operation 208 of the method 200, the deposition cycle includes exposing the workpiece to a fourth gas containing a second precursor to deposit a silicon film. The second precursor differs from the first precursor. In one example, the second precursor is a higher order silicon precursor. For example, the second precursor is a disilane, trisilane, tetrasilane, or another higher order silicon precursor. In one example, the second precursor is a combination of two or more higher order silicon precursors. With reference to FIG. 1A, the workpiece 100 is exposed to the fourth gas to deposit the silicon film 140 on the silicon-germanium layer 130.

In one example, depositing the silicon film 140 includes depositing the silicon seed layer 142 on the silicon-germanium layer 130. In one or more examples, to deposit the silicon seed layer 142, the fourth gas contains a silicon-chlorine precursor. In one or more examples, depositing the silicon seed layer 142 is omitted.

In one or more examples, depositing the silicon film 140 includes depositing the silicon bulk layer 144. The silicon bulk layer 144 is deposited on the silicon seed layer 142. In such an example, before the silicon bulk layer 144 is deposited the flow of the silicon-chlorine precursor is ceased. The workpiece 100 is exposed to a fifth gas comprising the second precursor and the carrier gas to deposit the silicon bulk layer 144. In an example where the silicon seed layer 142 is omitted, the silicon bulk layer 144 is deposited on the carbon-doped silicon germanium stack 104 in the presence of the fourth gas.

In one or more examples, the use of a higher order silicon precursor as the second precursor during the deposition of the silicon film increases the growth rate of the silicon layers and allows for the thickness of the first and/or second silicon-germanium layers 110/130 to be reduced. Accordingly, the thickness of the carbon-silicon germanium layer 130 relative to the thickness of the carbon-doped silicon germanium stack 104 is increased, improving the performance of the corresponding device.

The operations 202-208 of the method 200 can be repeated to prepare the multi-layered epitaxial stack 108 containing one or more of the carbon-doped silicon-germanium and silicon mini-stacks 106 on the substrate 102. The deposition cycle is repeated in a range from about 1, 2, 3, 4, 5, 6, 8, 10, about 12, about 15, about 20, about 25, about 30, about 40, or about 50 times to about 60, about 70, about 80, about 90, about 100, about 120, about 140, about 150, about 160, about 180, about 200, about 250, or more times to prepare the multi-layered epitaxial stack 108. For example, the deposition cycle can be repeated from about 2 times to about 250 times, about 5 times to about 200 times, about 10 times to about 200 times, about 20 times to about 200 times, about 30 times to about 200 times, about 40 times to about 200 times, about 50 times to about 200 times, about 80 times to about 200 times, about 100 times to about 200 times, about 120 times to about 200 times, about 150 times to about 200 times, about 180 times to about 200 times, about 5 times to about 100 times, about 10 times to about 100 times, about 20 times to about 100 times, about 30 times to about 100 times, about 40 times to about 100 times, about 50 times to about 100 times, about 60 times to about 100 times, about 80 times to about 100 times, or about 90 times to about 100 times to prepare the multi-layered epitaxial stack 108.

In one or more examples, the deposition cycle, including operations 202-208, can be repeated from about 10 times to about 200 times to prepare the multi-layered epitaxial stack 108. In other examples, the deposition cycle can be repeated from about 30 times to about 100 times to prepare the multi-layered epitaxial stack 108. In some examples, the deposition cycle can be repeated from about 40 times to about 80 times to prepare the multi-layered epitaxial stack 108.

In one or more examples, the method 200 is performed at temperatures of less than about 600° C. In one or more examples, the method 200 is performed at temperatures of less than about 450° C. In one or more examples, the method 200 is performed at pressures in a range of about 1 mTorr to about 100 mTorr. In other examples, pressures of less than 1 mTorr or greater than 100 mTorr may be used.

In one or more embodiments, after completing operations 202-208 of the method 200, additional processes can be conducted, although not depicted in FIG. 2A. For example, the method can include further exposing the workpiece 100 containing the multi-layered epitaxial stack 108 disposed on the substrate 102 to one or more annealing processes. The annealing processes can be or include a furnace anneal process, a spike anneal process, a rapid thermal anneal process, or any combination thereof.

After the annealing process, the multi-layered epitaxial stack 108 can have a slipline count of less than 6,000 sliplines, less than 5,000 sliplines, less than 4,000 sliplines, less than 3,000 sliplines, less than 2,000 sliplines, or less than 1,000 sliplines. In some examples, the multi-layered epitaxial stack 108 can have a slipline count in a range from about 100 sliplines, about 200 sliplines, about 300 sliplines, about 400 sliplines, or about 500 sliplines to about 600 sliplines, about 700 sliplines, about 800 sliplines, about 900 sliplines, about or less than 1,000 sliplines, about or less than 2,000 sliplines, about or less than 3,000 sliplines, about or less than 4,000 sliplines, about or less than 5,000 sliplines, or about or less than 6,000 sliplines after the annealing process. For example, the multi-layered epitaxial stack 108 can have a slipline count of about 100 sliplines to about 5,000 sliplines, about 100 sliplines to about 4,000 sliplines, about 100 sliplines to about 3,000 sliplines, about 100 sliplines to about 2,000 sliplines, or about 100 sliplines to about 1,000 sliplines after the annealing process.

In one or more examples, the annealing process is a furnace anneal process. The workpiece 100 is heated to a temperature of about 500° C. to about 750° C. for a period of about 5 hours to about 20 hours during the furnace anneal process. The multi-layered epitaxial stack 108 has a slipline count of about 100 sliplines to about 2,000 sliplines after the furnace annealing process.

In other examples, the annealing process is a spike anneal process. The workpiece 100 is heated to a temperature of about 1,050° C. for a period of about 1 second to about 100 seconds during the spike anneal process. The multi-layered epitaxial stack 108 has a slipline count of less than 6,000 sliplines after the spike annealing process.

FIG. 2B is a flowchart depicting a process or method 210 for fabricating a multi-layered epitaxial stack, such as the multi-layered epitaxial stack 158 disposed on the substrate 102, according to one or more embodiments described and discussed herein. Other multi-layered epitaxial stacks and various film stacks can be deposited, fabricated, or otherwise produced by the method 210.

In one or more embodiments, the method 210 is provided and includes sequentially depositing a carbon-doped silicon germanium stack 154 and a silicon film 140 to form a carbon-doped silicon-germanium and silicon mini-stack disposed on a substrate 102 during a deposition cycle. The method 210 includes repeating the deposition cycle to prepare a multi-layered epitaxial stack 158 containing one or more of the carbon-doped silicon-germanium and silicon mini-stacks 156 on the substrate 102.

At operation 212 of the method 210, the deposition cycle includes exposing the workpiece to a first gas to deposit a carbon-silicon-germanium layer on the first silicon-germanium layer. With reference to FIG. 1B, the workpiece 150 is exposed to a first gas containing a silicon precursor, a silicon-chlorine precursor, a silicon-carbon precursor, a germanium precursor, and a carrier gas to deposit the carbon-silicon-germanium layer 120 on the substrate 102.

In one example, before the operation 212 the flow of one or more silicon-carbon precursors is started. The silicon-carbon precursor contains one or more alkylsilanes. In some examples, the silicon-carbon precursor can be or contain methylsilane, dimethylsilane, or any combination thereof.

In one example after the completion of the operation 212, the deposition cycle includes ceasing the flow of the one or more silicon-carbon precursors.

At operation 214 of the method 210, the deposition cycle includes exposing the workpiece to a second gas containing a second precursor to deposit a silicon film. The second precursor differs from the first precursor. In one example, the second precursor is a higher order silicon precursor. For example, the second precursor is a disilane, trisilane, tetrasilane, or another higher order silicon precursor. In one example, the second precursor is a combination of two or more higher order silicon precursors. With reference to FIG. 1B, the workpiece 150 is exposed to the second gas to deposit the silicon film 140 on the carbon-silicon-germanium layer 120.

In one example, depositing the silicon film 140 includes depositing the silicon seed layer 142 on the carbon-silicon-germanium layer 120. In one or more examples, to deposit the silicon seed layer 142, the second gas contains a silicon-chlorine precursor. In one or more examples, depositing the silicon seed layer 142 is omitted.

In one or more examples, depositing the silicon film 140 includes depositing the silicon bulk layer 144. The silicon bulk layer 144 is deposited on the silicon seed layer 142. In such an example, before the silicon bulk layer 144 is deposited the flow of the silicon-chlorine precursor is ceased. The workpiece 150 is exposed to a third gas comprising the second precursor and the carrier gas to deposit the silicon bulk layer 144. In an example where the silicon seed layer 142 is omitted, the silicon bulk layer 144 is deposited on the carbon-doped silicon germanium stack 104 in the presence of the second gas.

In one or more examples, the use of a higher order silicon precursor as the second precursor during the deposition of the silicon film increases the growth rate of the silicon layers.

The operations 212 and 214 of the method 210 can be repeated to prepare the multi-layered epitaxial stack 158 containing one or more of the carbon-doped silicon-germanium and silicon mini-stacks 156 on the substrate 102. The deposition cycle is repeated in a range from about 1, 2, 3, 4, 5, 6, 8, 10, about 12, about 15, about 20, about 25, about 30, about 40, or about 50 times to about 60, about 70, about 80, about 90, about 100, about 120, about 140, about 150, about 160, about 180, about 210, about 250, or more times to prepare the multi-layered epitaxial stack 158. For example, the deposition cycle can be repeated from about 2 times to about 250 times, about 5 times to about 210 times, about 10 times to about 210 times, about 20 times to about 210 times, about 30 times to about 210 times, about 40 times to about 210 times, about 50 times to about 210 times, about 80 times to about 210 times, about 100 times to about 210 times, about 120 times to about 210 times, about 150 times to about 210 times, about 180 times to about 210 times, about 5 times to about 100 times, about 10 times to about 100 times, about 20 times to about 100 times, about 30 times to about 100 times, about 40 times to about 100 times, about 50 times to about 100 times, about 60 times to about 100 times, about 80 times to about 100 times, or about 90 times to about 100 times to prepare the multi-layered epitaxial stack 158.

In one or more examples, the deposition cycle, including operations 212-214, can be repeated from about 10 times to about 210 times to prepare the multi-layered epitaxial stack 108. In other examples, the deposition cycle can be repeated from about 30 times to about 100 times to prepare the multi-layered epitaxial stack 108. In some examples, the deposition cycle can be repeated from about 40 times to about 80 times to prepare the multi-layered epitaxial stack 108.

In one or more examples, the method 210 is performed at temperatures of less than about 600° C. In one or more examples, the method 210 is performed at temperatures of less than about 450° C. In one or more examples, the method 210 is performed at pressures in a range of about 1 mTorr to about 100 mTorr. In other examples, pressures of less than 1 mTorr or greater than 100 mTorr may be used.

In one or more embodiments, after completing operations 212-214 of the method 210, additional processes can be conducted, although not depicted in FIG. 2B. For example, the method can include further exposing the workpiece 150 containing the multi-layered epitaxial stack 158 disposed on the substrate 102 to one or more annealing processes. The annealing processes can be or include a furnace anneal process, a spike anneal process, a rapid thermal anneal process, or any combination thereof.

After the annealing process, the multi-layered epitaxial stack 158 can have a slipline count of less than 6,000 sliplines, less than 5,000 sliplines, less than 4,000 sliplines, less than 3,000 sliplines, less than 2,000 sliplines, or less than 1,000 sliplines. In some examples, the multi-layered epitaxial stack 158 can have a slipline count in a range from about 100 sliplines, about 210 sliplines, about 300 sliplines, about 400 sliplines, or about 500 sliplines to about 600 sliplines, about 700 sliplines, about 800 sliplines, about 900 sliplines, about or less than 1,000 sliplines, about or less than 2,000 sliplines, about or less than 3,000 sliplines, about or less than 4,000 sliplines, about or less than 5,000 sliplines, or about or less than 6,000 sliplines after the annealing process. For example, the multi-layered epitaxial stack 158 can have a slipline count of about 100 sliplines to about 5,000 sliplines, about 100 sliplines to about 4,000 sliplines, about 100 sliplines to about 3,000 sliplines, about 100 sliplines to about 2,000 sliplines, or about 100 sliplines to about 1,000 sliplines after the annealing process.

In one or more examples, the annealing process is a furnace anneal process. The workpiece 150 is heated to a temperature of about 500° C. to about 750° C. for a period of about 5 hours to about 20 hours during the furnace anneal process. The multi-layered epitaxial stack 158 has a slipline count of about 100 sliplines to about 2,000 sliplines after the furnace annealing process.

In other examples, the annealing process is a spike anneal process. The workpiece 150 is heated to a temperature of about 1,050° C. for a period of about 1 second to about 150 seconds during the spike anneal process. The multi-layered epitaxial stack 108 has a slipline count of less than 6,000 sliplines after the spike annealing process.

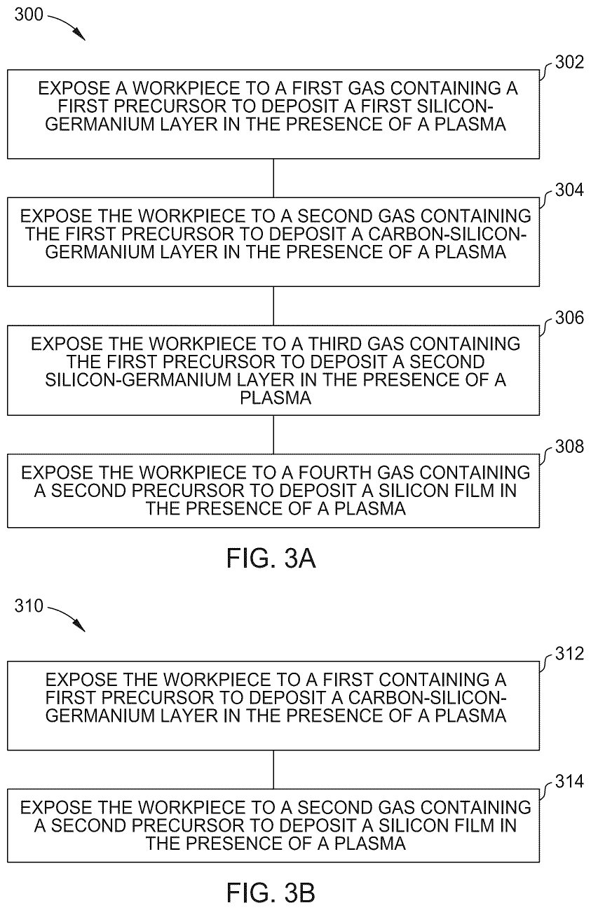

FIG. 3A is a flowchart depicting a process or method 300 for fabricating a multi-layered epitaxial stack, such as the multi-layered epitaxial stack 108 disposed on the substrate 102, according to one or more embodiments described and discussed herein. The method 300 describes fabricating the multi-layered epitaxial stack in the presence of a plasma. Further, as is described above with regard to the method 200, other multi-layered epitaxial stacks and various film stacks can be deposited, fabricated, or otherwise produced by the method 300.

In one or more examples, the method 300 includes sequentially depositing a carbon-doped silicon germanium stack 104 and a silicon film 140 to form a carbon-doped silicon-germanium and silicon mini-stack disposed on a substrate 102 during a deposition cycle. The method 300 includes repeating the plasma deposition cycle to prepare a multi-layered epitaxial stack 108 containing one or more of the carbon-doped silicon-germanium and silicon mini-stacks 106 on the substrate 102.

At operation 302 of the method 300, the deposition cycle includes exposing the workpiece containing a substrate to a first gas containing a first precursor to deposit a first silicon-germanium layer in the presence of a plasma. With reference to FIG. 1A, the workpiece 100 containing the substrate 102 is exposed to one or more of a silicon precursor, a silicon-chlorine precursor, a germanium precursor, and a carrier gas to deposit a first silicon-germanium layer 110 in the presence of a plasma. The silicon precursor contains silane. The silicon-chlorine precursor can be or contain one or more of monochlorosilane, dichlorosilane, trichlorosilane, tetracholorosilane, hexachlorodisilane, or any combination thereof. The germanium precursor can be or contain one or more of germane, tetrachlorogermane, one or more organogermane compounds, or any combination thereof. The carrier gas can be or contain on or more of hydrogen (H₂), nitrogen (N₂), argon, helium, or any combination thereof. In some examples, the carrier gas contains a mixture of hydrogen and nitrogen. The mixture of hydrogen and nitrogen can have a hydrogen to nitrogen molar ratio in a range from about 1:10 to about 10:1, about 1:5 to about 5:1, about 1:3 to about 3:1, about 1:2 to about 2:1, or about 1:1.

In one example, a purge gas may be delivered to the substrate before operation 302. The purge gas can include a nonreactive gas, e.g., a nitrogen-containing gas such as diatomic nitrogen, an argon-containing gas such as argon, or a helium-containing gas, such as helium. In an embodiment, the purge gas may be delivered to the substrate at a flow rate of about 1500 sccm to about 2500 sccm, e.g., about 1500 sccm to about 1600 sccm, about 1600 sccm to about 1700 sccm, about 1700 sccm to about 1800 sccm, about 1800 sccm to about 1900 sccm, about 1900 sccm to about 2000 sccm, about 2000 sccm to about 2100 sccm, about 2100 sccm to about 2200 sccm, about 2200 sccm to about 2300 sccm, about 2300 sccm to about 2400 sccm, or about 2400 sccm to about 2500 sccm.

In an embodiment, one or more radicals (also referred to as reactive gas), and/or charged ions are produced by the plasma and introduced to the processing chamber to deposit the first silicon-germanium layer 110. In one example, the plasma is generated in a remote plasma source (RPS) outside a processing chamber performing the deposition process. The radicals may be flowed into the processing chamber along with a carrier gas (e.g., Ar, H₂, or N₂). In another example, the plasma is generated within the processing chamber performing the deposition process.

At operation 304 of the method 300, the deposition cycle includes exposing the workpiece to a second gas to deposit a carbon-silicon-germanium layer on the first silicon-germanium layer in the presence of a plasma. With reference to FIG. 1A, the workpiece 100 is exposed to a second gas containing the silicon precursor, the silicon-chlorine precursor, the silicon-carbon precursor, the germanium precursor, and the carrier gas in the presence of a plasma to deposit the carbon-silicon-germanium layer 120 on the first silicon-germanium layer 110.

At operation 306 of the method 300, the deposition cycle includes exposing the workpiece to a third gas containing the first precursor to deposit a second silicon-germanium layer on the carbon-silicon-germanium layer in the presence of a plasma. The third gas contains the silicon precursor, the silicon-chlorine precursor, and the germanium precursor. With reference to FIG. 1A, exposing the workpiece to the third gas and the carrier gas in the presence of a plasma deposits a second silicon-germanium layer 130 on the carbon-silicon-germanium layer 120.

At operation 308 of the method 300, the deposition cycle includes exposing the workpiece to a fourth gas containing a second precursor to deposit a silicon film in the presence of a plasma. The second precursor differs from the first precursor. In one example, the second precursor is a higher order silicon precursor. For example, the second precursor is a disilane, trisilane, tetrasilane, or another higher order silicon precursor. In one example, the second precursor is a combination of two or higher order silicon precursors. With reference to FIG. 1A, the workpiece 100 is exposed to the fourth gas to deposit the silicon film 140 on the silicon-germanium layer 130.

In one example, depositing the silicon film 140 includes depositing the silicon seed layer 142 on the silicon-germanium layer 130 in the presence of a plasma. In one or more examples, to deposit the silicon seed layer 142, the fourth gas contains a silicon-chlorine precursor. In one or more examples, depositing the silicon seed layer 142 is omitted from the method 300.

In one or more examples, depositing the silicon film 140 includes depositing the silicon bulk layer 144. The silicon bulk layer 144 is deposited on the silicon seed layer 142. In such an example, before the silicon bulk layer 144 is deposited the flow of the silicon-chlorine precursor is ceased. The workpiece 100 is exposed to a fifth gas comprising the second precursor and the carrier gas to deposit the silicon bulk layer 144 in the presence of a plasma. In an example where the silicon seed layer 142 is omitted, the silicon bulk layer 144 is deposited on the carbon-doped silicon germanium stack 104 in the presence of the fourth gas.

As is described above with regard to the method 300, the operations 302-308 of the method 300 can be repeated to prepare the multi-layered epitaxial stack 108 containing one or more of the carbon-doped silicon-germanium and silicon mini-stacks 106 on the substrate 102. Further, as is described above with regard to the method 200, the annealing process may be performed after the completion of the deposition process.

In one or more examples, the workpiece is rotated when performing the method 300. In one or more examples, the method 300 is performed at temperatures of less than about 600° C. In one or more examples, the method 300 is performed at temperatures of less than about 450° C. In one or more examples, the method 300 is performed at pressures in a range of about 1 mTorr to about 100 mTorr. In other examples, pressures of less than 1 mTorr or greater than 100 mTorr may be used. In one example, one or more workpieces 100 may be processed using the method 300 within a common processing chamber.

FIG. 3B is a flowchart depicting a process or method 310 for fabricating a multi-layered epitaxial stack, such as the multi-layered epitaxial stack 158 disposed on the substrate 102, according to one or more embodiments described and discussed herein. The method 310 describes fabricating the multi-layered epitaxial stack in the presence of a plasma. Further, as is described above with regard to the method 250, other multi-layered epitaxial stacks and various film stacks can be deposited, fabricated, or otherwise produced by the method 310.

In one or more examples, the method 310 includes sequentially depositing a carbon-doped silicon germanium stack 154 and a silicon film 140 to form a carbon-doped silicon-germanium and silicon mini-stack disposed on a substrate 102 during a deposition cycle. The method 310 includes repeating the plasma deposition cycle to prepare a multi-layered epitaxial stack 158 containing one or more of the carbon-doped silicon-germanium and silicon mini-stacks 156 on the substrate 102.

At operation 312 of the method 310, the deposition cycle includes exposing the workpiece to a first gas to deposit a carbon-silicon-germanium layer on the first silicon-germanium layer in the presence of a plasma. With reference to FIG. 1B, the workpiece 150 is exposed to a first gas containing the silicon precursor, the silicon-chlorine precursor, the silicon-carbon precursor, the germanium precursor, and the carrier gas in the presence of a plasma to deposit the carbon-silicon-germanium layer 120 on the substrate.

The silicon-chlorine precursor can be or contain one or more of monochlorosilane, dichlorosilane, trichlorosilane, tetracholorosilane, hexachlorodisilane, or any combination thereof. The germanium precursor can be or contain one or more of germane, tetrachlorogermane, one or more organogermane compounds, or any combination thereof. The carrier gas can be or contain on or more of hydrogen (H₂), nitrogen (N₂), argon, helium, or any combination thereof. In some examples, the carrier gas contains a mixture of hydrogen and nitrogen. The mixture of hydrogen and nitrogen can have a hydrogen to nitrogen molar ratio in a range from about 1:10 to about 10:1, about 1:5 to about 5:1, about 1:3 to about 3:1, about 1:2 to about 2:1, or about 1:1.

In one example, a purge gas may be delivered to the substrate before operation 302. The purge gas can include a nonreactive gas, e.g., a nitrogen-containing gas such as diatomic nitrogen, an argon-containing gas such as argon, or a helium-containing gas, such as helium. In an embodiment, the purge gas may be delivered to the substrate at a flow rate of about 1500 sccm to about 2500 sccm, e.g., about 1500 sccm to about 1600 sccm, about 1600 sccm to about 1700 sccm, about 1700 sccm to about 1800 sccm, about 1800 sccm to about 1900 sccm, about 1900 sccm to about 2000 sccm, about 2000 sccm to about 2100 sccm, about 2100 sccm to about 2200 sccm, about 2200 sccm to about 2300 sccm, about 2300 sccm to about 2400 sccm, or about 2400 sccm to about 2500 sccm.

In an embodiment, one or more radicals (also referred to as reactive gas), and/or charged ions are produced by the plasma and introduced to the processing chamber to deposit the first silicon-germanium layer 110. In one example, the plasma is generated in a remote plasma source (RPS) outside a processing chamber performing the deposition process. The radicals may be flowed into the processing chamber along with a carrier gas (e.g., Ar, H₂, or N₂). In another example, the plasma is generated within the processing chamber performing the deposition process.

At operation 314 of the method 310, the deposition cycle includes exposing the workpiece to a second gas containing a second precursor to deposit a silicon film in the presence of a plasma. The second precursor differs from the first precursor. In one example, the second precursor is a higher order silicon precursor. For example, the second precursor is a disilane, trisilane, tetrasilane, or another higher order silicon precursor. In one example, the second precursor is a combination of two or higher order silicon precursors. With reference to FIG. 1B, the workpiece 150 is exposed to the second gas to deposit the silicon film 140 on the carbon-silicon-germanium layer 120.

In one example, depositing the silicon film 140 includes depositing the silicon seed layer 142 on the carbon-silicon-germanium layer 120 in the presence of a plasma. In one or more examples, to deposit the silicon seed layer 142, the second gas contains a silicon-chlorine precursor. In one or more examples, depositing the silicon seed layer 142 is omitted from the method 310.

In one or more examples, depositing the silicon film 140 includes depositing the silicon bulk layer 144. The silicon bulk layer 144 is deposited on the silicon seed layer 142. In such an example, before the silicon bulk layer 144 is deposited the flow of the silicon-chlorine precursor is ceased. The workpiece 150 is exposed to a third gas comprising the second precursor and the carrier gas to deposit the silicon bulk layer 144 in the presence of a plasma. In an example where the silicon seed layer 142 is omitted, the silicon bulk layer 144 is deposited on the carbon-doped silicon germanium stack 104 in the presence of the second gas.

As is described above with regard to the method 310, the operations 312-314 of the method 310 can be repeated to prepare the multi-layered epitaxial stack 158 containing one or more of the carbon-doped silicon-germanium and silicon mini-stacks 106 on the substrate 102. Further, as is described above with regard to the method 210, the annealing process may be performed after the completion of the deposition process.

In one or more examples, the workpiece is rotated when performing the method 310. In one or more examples, the method 310 is performed at temperatures of less than about 600° C. In one or more examples, the method 310 is performed at temperatures of less than about 450° C. In one or more examples, the method 310 is performed at pressures in a range of about 1 mTorr to about 100 mTorr. In other examples, pressures of less than 1 mTorr or greater than 100 mTorr may be used. In one example, one or more workpieces 100 may be processed using the method 310 within a common processing chamber.

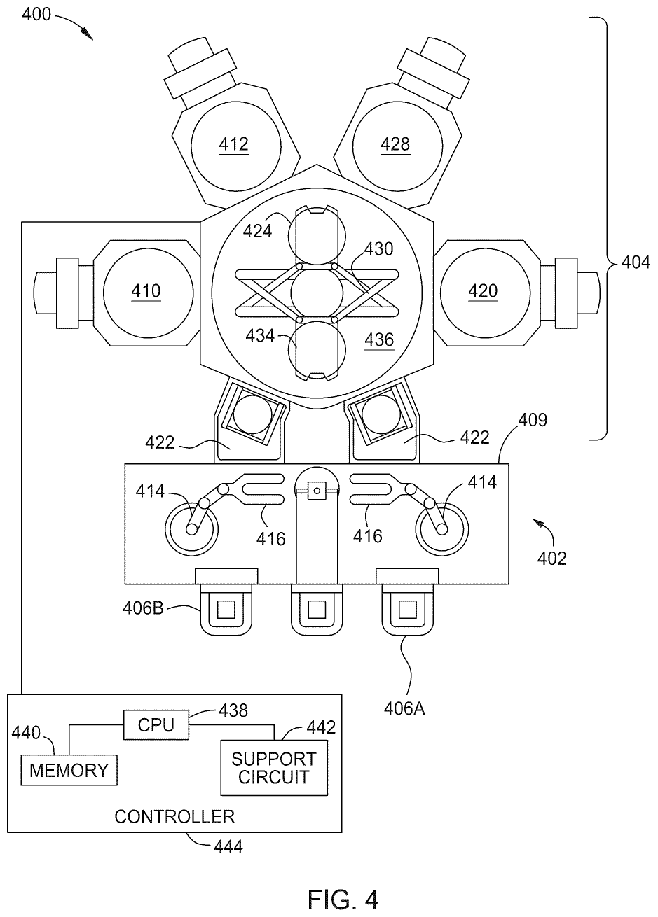

FIG. 4 illustrates a processing system 400 in accordance with one or more embodiments of the present disclosure. The embodiment shown in FIG. 4 is merely representative of one possible configuration and should not be taken as limiting the scope of the disclosure. For example, in some embodiments, the processing system 100 has a different number of processing chambers, load lock chambers, transfer chambers, and/or other components, and/or a configuration different from the illustrated embodiment.

The processing system 400 includes a processing platform 404 coupled with a factory interface 402 and a controller 444.

The processing platform 404 includes a plurality of processing chambers 410, 412, 420, 428, one or more load lock chambers 422, and a transfer chamber 436 that is coupled to the one or more load lock chambers 422.

The processing chambers 410, 412, 420, and 428 can be configured to perform any suitable process and provide any suitable process conditions. For example, one or more of the processing chambers 410, 412, 420, 428 may include a chemical vapor deposition (CVD) chamber, an atomic layer deposition (ALD) chamber, a plasma enhanced chemical vapor deposition (PECVD) chamber, an epitaxy (EPI) chamber, a rapid thermal processing (RTP) chamber, a reactive ion etching (RIE) chamber, or other suitable chamber. In one or more examples, one or more of the processing chambers 410, 412, 420, 428 may be configured to function as an inductively coupled plasma (ICP) processing chamber, a capacitively coupled plasma (CCP) processing chamber, an etch soak chamber, a thermal processing chamber, a microwave plasma processing chamber, a UV exposure processing chamber, a laser processing chamber, a pumping chamber, an annealing chamber, and/or a metrology chamber or station. A processing chamber configured to operate as an ALD chamber may have a showerhead or vortex type gas injector. A processing chamber configured to operate as a plasma chamber may have one or more electrodes and/or grounded plate configurations to generate a plasma while allowing a plasma gas to flow toward the wafer. In one or more examples, a processing chamber configured to operate as a plasma chamber may include a showerhead for providing the carrier gas and/or plasma gas. In some embodiments, one or more of the processing chambers 410, 412, 420, 428 can be operably coupled to a remote plasma source (RPS) for remote plasma processing operations, e.g., remote plasma oxidation (RPO).

In one or more examples, the method 200 and the method 300 are performed by one or more of the processing chambers 410, 412, 420, 428. For example, the method 200 is performed by a CVD chamber, an ALD chamber, a PECVD chamber, or an EPI chamber. The method 300 is performed by a plasma chamber including an ICP or CCP chamber. In example, the method 300 is performed using a remote plasma or a directly generated plasma.

The transfer chamber 436 can be maintained under vacuum, or can be maintained at an ambient (e.g., atmospheric) pressure. Two load lock chambers 422 are shown in FIG. 4. Each of the load lock chambers 422 has a first port interfacing with the factory interface 402 and a second port interfacing with the transfer chamber 436. The transfer chamber 436 has a vacuum robot 430 disposed therein. The vacuum robot 430 has one or more blades 434 (two are shown in FIG. 4) capable of transferring the substrates 424 between the load lock chambers 422 and the processing chambers 410, 412, 420, and 428.

The factory interface 402 is coupled to the transfer chamber 436 through the load lock chambers 422. In one or more embodiments, the factory interface 402 includes at least one docking station 409 and at least one factory interface robot 414 to facilitate the transfer of substrates 424. The docking station 409 is configured to accept one or more front opening unified pods (FOUPs). Two FOUPS 406A, 406B are shown in the implementation of FIG. 4. The factory interface robot 414 having a blade 416 disposed on one end of the robot 414 is configured to transfer one or more substrates from the FOUPS 406A, 406B, through the load lock chambers 422, to the processing platform 404 for processing. Substrates being transferred can be stored at least temporarily in the load lock chambers 422.

The controller 444 is coupled to the processing system 400 and is used to control processes and methods, such as the operations of the methods described herein (for example the operations of the methods as described in other parts of the present disclosure). The controller 444 includes a central processing unit (CPU) 438, a memory 440 containing instructions, and support circuits 442 for the CPU. The controller 444 controls various items directly, or via other computers and/or controllers associated with particular process chamber and/or support system components.

The controller 444 can be a single controller that controls the entire processing system 400, or multiple controllers that control individual portions of the processing system 400. For example, the processing system 400 may include separate controllers for each of the individual processing chambers 410, 412, 420, 428, the transfer chamber 436, the factory interface 402, the robots 414, etc.

The controller 444 may be one of any form of general-purpose computer processor that can be used in an industrial setting for controlling various chambers and sub-processors. The memory 440 or computer readable medium of the controller 444 may be one or more of readily available memory such as random access memory (RAM), read only memory (ROM), floppy disk, hard disk, optical storage media (e.g., compact disc or digital video disc), flash drive, or any other form of digital storage, local or remote. The memory 440 can retain an instruction set that is operable by the processor (CPU 438) to control parameters and components of the processing system 400.

The support circuits 442 are coupled to the CPU 438 for supporting the processor in a conventional manner. These circuits include cache, power supplies, clock circuits, input/output circuitry and subsystems, and the like. One or more processes may be stored in the memory 440 as software routine that, when executed or invoked by the processor, causes the processor to control the operation of the processing system 400 or individual processing chambers in the manner described herein. The software routine may also be stored and/or executed by a second CPU (not shown) that is remotely located from the hardware being controlled by the CPU 438.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the controller 444 has one or more configurations to execute individual processes or sub-processes to perform the method. The controller 444 can be connected to and configured to operate intermediate components to perform the functions of the methods. For example, the controller 444 can be connected to and configured to control one or more of gas valves, actuators, motors, slit valves, vacuum control or other components.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of fabricating a film stack, the method comprising:
sequentially depositing a carbon-doped silicon germanium stack and a silicon film to form a carbon-doped silicon-germanium and silicon mini-stack disposed on a substrate during a deposition cycle, wherein the deposition cycle comprises:
exposing a workpiece comprising the substrate to a first gas comprising a first precursor to deposit a first silicon-germanium layer;
exposing the workpiece to a second gas comprising the first precursor to deposit a carbon-silicon-germanium layer on the first silicon-germanium layer;
exposing the workpiece to a third gas comprising the first precursor to deposit a second silicon-germanium layer on the carbon-silicon-germanium layer; and
exposing the workpiece to a fourth gas comprising a second precursor to deposit the silicon film on the second silicon-germanium layer, wherein the second precursor differs from the first precursor.

2. The method of claim 1, wherein the first precursor is a silane precursor.

3. The method of claim 1, wherein the second precursor is a higher order silicon precursor.

4. The method of claim 3, wherein the higher order silicon precursor comprises disilane, trisilane, tetrasilane, or a combination thereof.

5. The method of claim 1, wherein the first gas, the second gas, the third gas, and the fourth gas further comprise a carrier gas.

6. The method of claim 1, wherein the deposition cycle is repeated to prepare a multi-layered epitaxial stack comprising two or more of the carbon-doped silicon-germanium and silicon mini-stacks on the substrate.

7. The method of claim 1, wherein the workpiece is exposed to the first gas in a presence of a plasma to deposit the first silicon-germanium layer, wherein the workpiece is exposed to the second gas in a presence of the plasma to deposit the carbon-silicon-germanium layer on the first silicon-germanium layer, wherein the workpiece is exposed to the third gas in a presence of the plasma to deposit the second silicon-germanium layer on the carbon-silicon-germanium layer, and wherein the workpiece is exposed to the fourth gas in a presence of the plasma to deposit the silicon film on the second silicon-germanium layer.

8. The method of claim 1, wherein depositing the silicon film comprises depositing a silicon seed layer and a silicon bulk layer on the second silicon-germanium layer.

9. The method of claim 1, wherein the first gas further comprises at least one selected from the group consisting of a silane precursor, a silicon-chlorine precursor, and a germanium precursor, wherein the second gas further comprises at least one selected from the group consisting of the silane precursor, the silicon-chlorine precursor, a silicon-carbon precursor, and the germanium precursor, wherein the third gas further comprises at least one selected from the group consisting of the silane precursor, the silicon-chlorine precursor and the germanium precursor, and wherein the fourth gas further comprises at least one selected from the group consisting of a higher order silicon precursor and the silicon-chlorine precursor.

10. A processing chamber configured to:
sequentially deposit a carbon-doped silicon germanium stack and a silicon film to form a carbon-doped silicon-germanium and silicon mini-stack disposed on a substrate during a deposition cycle, wherein the deposition cycle comprises:
exposing a workpiece comprising the substrate to a first gas comprising a first precursor to deposit a first silicon-germanium layer;
exposing the workpiece to a second gas comprising the first precursor to deposit a carbon-silicon-germanium layer on the first silicon-germanium layer;
exposing the workpiece to a third gas comprising the first precursor to deposit a second silicon-germanium layer on the carbon-silicon-germanium layer; and
exposing the workpiece to a fourth gas comprising a second precursor to deposit the silicon film on the second silicon-germanium layer, wherein the second precursor differs from the first precursor.

11. The processing chamber of claim 10, wherein the first precursor is a silane precursor and the second precursor is a higher order silicon precursor.

12. The processing chamber of claim 10, wherein the second precursor is a higher order silicon precursor comprising disilane, trisilane, tetrasilane, or a combination thereof.

13. The processing chamber of claim 10, wherein the first gas, the second gas, the third gas, and the fourth gas further comprise a carrier gas.

14. The processing chamber of claim 10, wherein the workpiece is exposed to the first gas in a presence of a plasma to deposit the first silicon-germanium layer, wherein the workpiece is exposed to the second gas in a presence of the plasma to deposit the carbon-silicon-germanium layer on the first silicon-germanium layer, wherein the workpiece is exposed to the third gas in a presence of the plasma to deposit the second silicon-germanium layer on the carbon-silicon-germanium layer, and wherein the workpiece is exposed to the fourth gas in a presence of the plasma to deposit the silicon film on the second silicon-germanium layer.

15. The processing chamber of claim 10, wherein depositing the silicon film comprises depositing a silicon seed layer and a silicon bulk layer on the second silicon-germanium layer.

16. The processing chamber of claim 10, wherein the first gas further comprises at least one selected from the group consisting of a silane precursor, a silicon-chlorine precursor, and a germanium precursor, wherein the second gas further comprises at least one selected from the group consisting of the silane precursor, the silicon-chlorine precursor, a silicon-carbon precursor, and the germanium precursor, wherein the third gas further comprises at least one selected from the group consisting of the silane precursor, the silicon-chlorine precursor and the germanium precursor, and wherein the fourth gas further comprises at least one selected from the group consisting of a higher order silicon precursor and the silicon-chlorine precursor.

17. The processing chamber of claim 11, wherein the processing chamber is one of a chemical vapor deposition chamber, an atomic layer deposition chamber, and a plasma enhanced chemical vapor deposition (PECVD) chamber.

18. The processing chamber of claim 11, wherein the processing chamber is one of an inductively coupled plasma processing chamber and a capacitively coupled plasma processing chamber.

19. A workpiece, comprising:
a multi-layered epitaxial stack disposed on a substrate, the multi-layered epitaxial stack comprising:
a plurality of carbon-doped silicon-germanium stacks, wherein each of the plurality of carbon-doped silicon-germanium stacks is deposited in a presence of a first precursor; and
a plurality of silicon films, wherein each of the plurality of silicon films is deposited on a respective one of the plurality of carbon-doped silicon-germanium stacks, wherein each of the plurality of silicon films is deposited in a presence of a second precursor, and wherein the second precursor differs from the first precursor.

20. The workpiece of claim 19, wherein the first precursor is a silane precursor and the second precursor is a higher order silicon precursor.
